(19) United States
(12) Patent Application Publication
(10) Pub. No.: US 2010/0247747 A1
(43) Pub. Date: Sep. 30, 2010

(54) Film Deposition Apparatus, Method for Depositing Film, and Method for Manufacturing Lighting Device

(75) Inventor: Shunpei Yamazaki, Tokyo (JP)

Correspondence Address: COOK ALEX LTD, SUITE 2850, 200 WEST ADAMS STREET, CHICAGO, IL, 60606, US

(73) Assignee: Semiconductor Energy Laboratory Co., Ltd.

(21) Appl. No.: 12/729,881

(22) Filed: Mar. 23, 2010

(30) Foreign Application Priority Data
Mar. 27, 2009 (JP) 2009-080199

(51) Int. Cl. B05D 5/06; C23C 16/00; C23C 16/44; B05D 5/12; C23C 16/458

(52) U.S. Cl. 427/66; 118/729; 118/730; 427/255.5; 427/58; 427/255.23

(57) ABSTRACT

A first evaporation source is disposed such that one predetermined film deposition material is deposited on one region of a substrate; a second evaporation source is disposed such that another predetermined film deposition material is deposited on another region of the substrate; and the substrate is spun such that different materials are contained at a predetermined proportion on a film-deposition surface of the substrate. By disposing the plurality of evaporation sources at different positions, a thin film in which a plurality of materials are mixed, a thin film in which a plurality of materials are arranged in a grid pattern, or a thin film in which a plurality of monomolecular layers are stacked in a film thickness direction (the state can also be substantially called a super multi-monomolecular-layers) can be formed.

### BACKGROUND OF THE INVENTION

1. Field of the Invention

The present invention relate to a film deposition apparatus and a method for deposing a film.

2. Description of the Related Art

An organic electroluminescent element formed by stacking a thin film formed using an organic material is manufactured using a vacuum evaporation method. The vacuum evaporation method is a typical technique used for forming various kinds of thin films, and various structures of a vacuum evaporation apparatus have been devised to manufacture organic electroluminescent elements.

For example, a vacuum evaporation apparatus has been disclosed in which in order to stabilize the deposition rate, a container filled with an organic material is disposed so as to face a substrate on which the organic material is deposited and a heating wall is provided so as to surround the space between the container and the substrate (see Patent Document 1). It is said that according to this vacuum evaporation apparatus, the container filled with an organic material is heated while heating the heating wall at about the evaporation temperature of the organic material, so that the organic material is deposited on the substrate, whereby uniform deposition of the organic material on a substrate surface can be kept for a long period of time.

In addition, a vacuum evaporation apparatus has been disclosed in which in order to uniformize the thickness of each layer of an organic electroluminescent element within a substrate plane, crucibles which contain the same evaporation material are disposed at a plurality of portions within a vacuum container and the evaporation material of each crucible is deposited on the substrate (see Patent Document 2).

The light emission color of an organic electroluminescent element is controlled by adding a guest material at a slight amount to a host material. In that case, it is necessary to control the evaporation rates of the host material and the guest material with high precision. Since the vapor pressure of the guest material is different from that of the host material, it is necessary that temperatures of evaporation sources of the host material and the guest material are controlled separately by a co-evaporation method and that the guest material is mixed uniformly in the host material on the substrate surface on which an organic film is to be formed.

However, in the vacuum evaporation method, a host material and a guest material both exist in the space between an evaporation source and a substrate, which leads to association and aggregation of them in that space, so that it is difficult to precisely control the composition of an organic thin film stacked on the substrate. Further, the distance between the evaporation source (point evaporation source) and each region within a plane of the substrate which is a flat plate is not uniform, so that it is difficult to control the uniformity of the composition of the organic thin film stacked on the substrate.

### REFERENCE

Patent Document 1: Japanese Published Patent Application No. 2005-082872

Patent Document 2: Japanese Published Patent Application No. 2005-019090

### SUMMARY OF THE INVENTION

An aspect of the present invention is to provide a film deposition apparatus and/or a method for deposing a film, by which a thin film with high uniformity of thickness is formed. An aspect of the present invention is to provide a film deposition apparatus and/or a method for deposing a film, by which the composition of a thin film formed using a plurality of materials, as in the case where a guest material is added into a host material, can be controlled precisely.

One embodiment of the present invention is a film deposition apparatus including a plurality of evaporation sources disposed discretely, a substrate holding portion for holding a substrate at a position at which a film deposition material from the evaporation sources is splashed and deposited, and a driving portion for relatively moving either one or both of the plurality of evaporation sources and the substrate.

A film deposition apparatus in accordance with one embodiment of the present invention includes: a first evaporation source disposed such that a first film deposition material is deposited on one region in a surface of a substrate; a second evaporation source disposed such that a second film deposition material is deposited on another region in the surface of the substrate; and a driving portion for relatively moving the substrate and either one or both of the first and second evaporation sources such that different materials are contained at a predetermined proportion on the surface of the substrate. In that structure, the first evaporation source and the second evaporation source are cited as a typical example; a thin film made of a multi-component material can be formed by disposing a plurality of evaporation sources.

In the film evaporation apparatus having the above-described structure, the shape of the substrate is not particularly limited; for example, a circular (disc-like shape) substrate can be applied. In that case, the substrate is spun about a central axis and each evaporation source is disposed at a position away from the central axis such that a predetermined film deposition material is deposited on one region of the substrate which is spun. By disposing the plurality of evaporation sources at different positions, a thin film in which a plurality of materials are mixed to control the composition of the thin film precisely or a thin film in which layers formed using a plurality of monomolecular layers of a plurality of materials are stacked in a film thickness direction (the state can also be substantially called a super multi-monomolecular-layers structure) can be formed.

The spinning speed of the substrate is determined as appropriate depending on the deposition rate of the material discharged from the evaporation source. The spinning speed of the substrate serves as parameters of the thickness of the film to be deposited on the region. When the spinning speed is fixed, the number of evaporation sources disposed with respect to the substrate serves as the parameters of the thickness. By spinning at a speed at which a monomolecular layer is substantially formed using the film deposition materials, such a thin film in which a plurality of materials is stacked uniformly or periodically as described above can be obtained. A spinning rate in the range from 300 rpm (rotation per minute) to 30000 rpm, typically 1000 rpm, is employed.

One embodiment of the present invention is a film deposition method in which a plurality of evaporation sources are disposed discretely, and a substrate is held at a position at which a film deposition material is splashed and deposited from the evaporation source while either one or both of the plurality of evaporation sources and the substrate are relatively moved, whereby one or a plurality of thin films is formed over a surface of the substrate.

One embodiment of the present invention is a film deposition method in which: a first evaporation source is disposed such that a first film deposition material is deposited on one region in a surface of a substrate; a second evaporation source is disposed such that second film deposition material is deposited on another region in the surface of the substrate; and either one or both of the substrate and the first and second evaporation sources are relatively moved such that a thin film is formed to contain materials supplied form the first and second evaporation sources at a predetermined proportion on the surface of the substrate.

One embodiment of the present invention is a film deposition method in which: a first evaporation source is disposed such that a first film deposition material is deposited on one region of a substrate; a second evaporation source is disposed such that a second film deposition material is deposited on another region of the substrate; alternating a first step of attaching the first film deposition material supplied from the first evaporation source on one region in a surface of the substrate and a second step of attaching the second film deposition material supplied from the second evaporation source on the one region in the surface of the substrate to form a thin film over the surface of the substrate while the substrate is spun using a center of the substrate as a center of the spin.

In a film deposition method in accordance with one embodiment of the present invention, a substrate having any shape can be used. For example, a circular (disc-like shape) substrate can be applied in this film deposition method. In the case where a circular substrate is used, the substrate is spun about a central axis, and an evaporation source is held such that a predetermined film deposition material is deposited on one region of the substrate which is spun. For example, evaporation sources are held such that different materials such as a guest material and a host material are deposited on different regions within a film-deposition plane of a substrate, and a circular substrate is spun, so that film deposition is performed. In this manner, a thin film in which a plurality of monomolecular layers formed using different materials are stacked in a film thickness direction (the state can also be substantially called a super multi-monomolecular-layers structure) can be formed.

In this film deposition method, the spinning speed (or spinning rate) of the substrate is one factor in the film deposition condition. The spinning speed of the substrate serves as parameters of the thickness of the film deposited on the region. When the spinning speed is fixed, the number of evaporation sources disposed with respect to the substrate serves as the parameters of the thickness. By relatively moving the substrate and the evaporation sources, one material and another material are deposited alternatively on a substrate surface, which results in uniform and/or periodical deposition of a plurality of materials depositing a plurality of materials uniformly or periodically.

By the above-described film deposition method, an electroluminescent element formed by precisely controlling the proportion of a guest material and a host material can be manufactured. Further, a display device and/or a lighting device using an electroluminescent element can be manufactured.

According to one aspect of the present invention, a substrate and an evaporation source are disposed to have a predetermined relation and the substrate and the evaporation source are relatively moved, so that a thin film with high uniformity can be formed.

According to one aspect of the present invention, evaporation sources are held such that different materials such as a guest material and a host material are deposited on respective different regions within a film-deposition plane of a substrate and film deposition is performed while a circular substrate is spun, whereby the composition of a thin film can be controlled precisely.

### BRIEF DESCRIPTION OF THE DRAWINGS

FIG. 1 is a plane view of a structure of a film deposition chamber of a film deposition apparatus.

FIG. 2 is a cross-sectional view of a structure of a film deposition chamber of a film deposition apparatus.

FIGS. 3A and 3B are cross-sectional views each schematically illustrating a structure of a thin film.

FIGS. 4A and 4B are conceptual diagrams of the case where a guest material and a host material are co-evaporated: FIG. 4A illustrates the conventional case; and FIG. 4B illustrates the case of one embodiment of the present invention.

FIG. 5 is a cross-sectional view of a structure of an evaporation source.

FIG. 6 is a plane view of a structure of a film deposition apparatus.

FIG. 7 is a cross-sectional view of a structure of a film deposition apparatus.

FIG. 8 is a cross-sectional view of a stacked-layer structure of a lighting device.

FIG. 9 is a plane view of a structure of a lighting device.

FIGS. 10A and 10B are cross-sectional views each illustrating a structure of a lighting device.

FIGS. 11A to 11D are cross-sectional views each illustrating a structure of a lighting device.

FIGS. 12A and 12B are cross-sectional views each illustrating an attachment structure of a lighting device.

### DETAILED DESCRIPTION OF THE INVENTION

Hereinafter, embodiments of the present invention will be described with reference to accompanying drawings. Note that the present invention is not limited to the description below, and it is easily understood by those skilled in the art that a variety of changes and modifications can be made without departing from the spirit and scope of the present invention. Therefore, the present invention is not to be construed as being limited to the description of the embodiments below. Note that reference numerals may be used in common to denote portions among different drawings in the embodiments described below. The thickness, width, relative relation of position, and the like of elements illustrated in the drawings are exaggerated for clarification of description of the embodiments in some cases.

### (Structural Embodiment of Film Deposition Chamber)

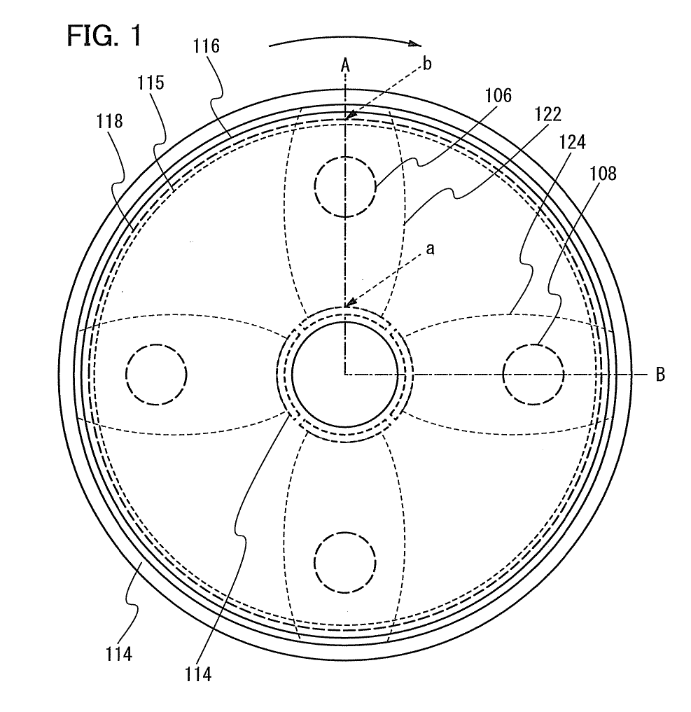

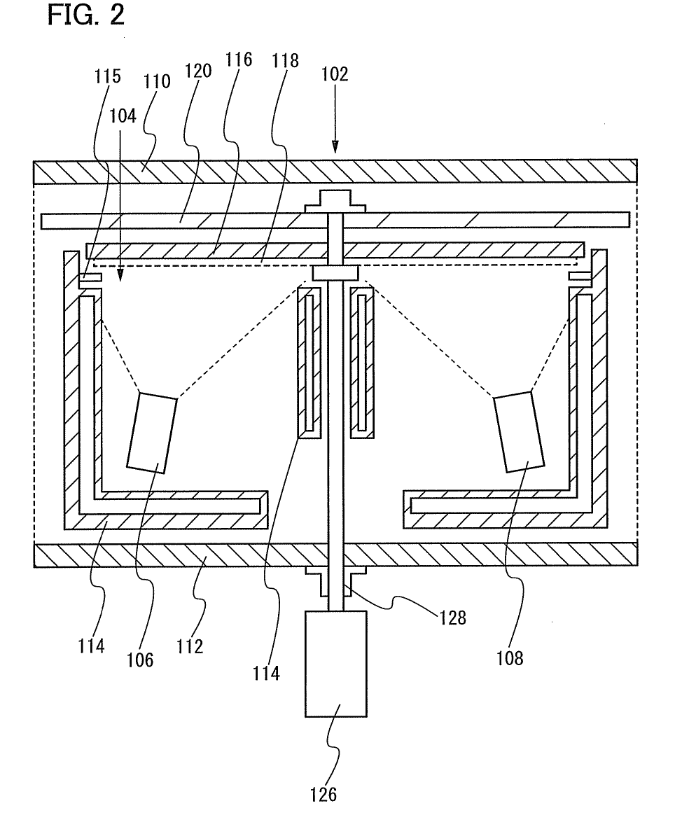

A main structure of a film deposition apparatus in accordance with one embodiment of the present invention is illustrated in FIGS. 1 and 2. FIG. 1 is a plane view of the film deposition apparatus, and FIG. 2 is a cross-sectional view which is roughly taken along cut line A-B in FIG. 1. Description below will be given with reference to FIGS. 1 and 2.

A film deposition chamber 104 is provided in a treatment chamber 102 in which the pressure is kept low by vacuum evacuation. The treatment chamber 102 includes a chamber top plate 110 and a chamber bottom plate 112 and the film deposition chamber 104 is provided between the chamber top plate 110 and the chamber bottom plate 112. The film deposition chamber 104 is structured such that a first evaporation source 106 and a second evaporation source 108 are surrounded by a deposition shield 114.

The deposition shield 114 is hollow. Heated fluid flows through the hollow in the deposition shield 114. For example, silicone oil or the like is used as the fluid. By supplying heated fluid into the hollow in the deposition shield 114 to heat the deposition shield 114 to a temperature as high as a material discharged from an evaporation source is not attached to, the use efficiency of the material can be improved. The use efficiency of a material refers to the proportion of a material attached to a substrate to form a film with respect to a total material which is evaporated or sublimed from an evaporation source.

The first evaporation source 106 is disposed so as to face a substrate 118 held by a substrate holder 116. The substrate holder 116 is coupled to a transfer table 120. Arrangement is performed such that vapor discharged from the first evaporation source 106 is not deposited over an entire surface of the substrate 118 but is deposited on one region of the substrate 118. The same structure can be applied to the second evaporation source 108.

In FIG. 1, a first film deposition region 122 formed by the first evaporation source 106 is schematically illustrated. A second film deposition region 124 is formed by the second evaporation source 108 in a similar manner. The first film deposition region 122 and the second film deposition region 124 are not necessarily distinguished clearly. By spacing the first evaporation source 106 and the second evaporation source 108, regions of the substrate 118 on which materials of the first evaporation source 106 and the second evaporation source 108 are preferentially deposited exist. In the case where the film deposition regions are clearly distinguished, a shield may be provided between the first evaporation source 106 and the second evaporation source 108.

In the first film deposition region 122, it is preferable that the film thickness distribution on the line from the center of the substrate 118 to the outer circumference, indicated by line a-b in FIG. 1 be uniform. Therefore, the first evaporation source 106 and the second evaporation source 108 may be arranged such that their respective vapor discharge outlets face the center of the substrate 118 in consideration of their deposition rates.

When a thin film is formed on the substrate 118, either one or both of the substrate 118 and the first evaporation source 106 and the second evaporation source 108 are moved relatively by a driving portion 126. For example, the substrate is spun with respect to the evaporation source(s). In that case, the driving portion 126 is coupled to the substrate holder 116 by a spinning axis 128. By thus doing, the first film deposition region 122 and the second film deposition region 124 are formed alternatively on one point of the substrate 118, which enables deposition of a thin film over an entire surface of the substrate 118. The outer circumference of the substrate 118 may be covered with a mask 115 such that a film is not deposited thereon. The size of this mask 115 can be determined as appropriate.

The same material may be supplied to the first evaporation source 106 and the second evaporation source 108; different materials may be supplied to the first evaporation source 106 and the second evaporation source 108. In the case where a thin film of a compound is formed on the substrate 118, elements contained in the compound may be set in their respective different evaporation sources. In the case where a guest material is added into a host material, the host material and the guest material may be set in their respective evaporation sources. The number of evaporation sources disposed may be two or more; the above described structure of an evaporation source can be applied to that case.

The shape of the substrate which is applicable to the film deposition apparatus having the above-described structure is not particularly limited; for example, it is preferable to employ a circular (disc-like shape) substrate. In the case where the substrate 118 is used, a pass-through opening can be provided in the center thereof. In that case, the substrate is spun about a central axis, and an evaporation source is disposed at a position away from the central axis such that a predetermined film deposition material is deposited on one region of the substrate which is spun.

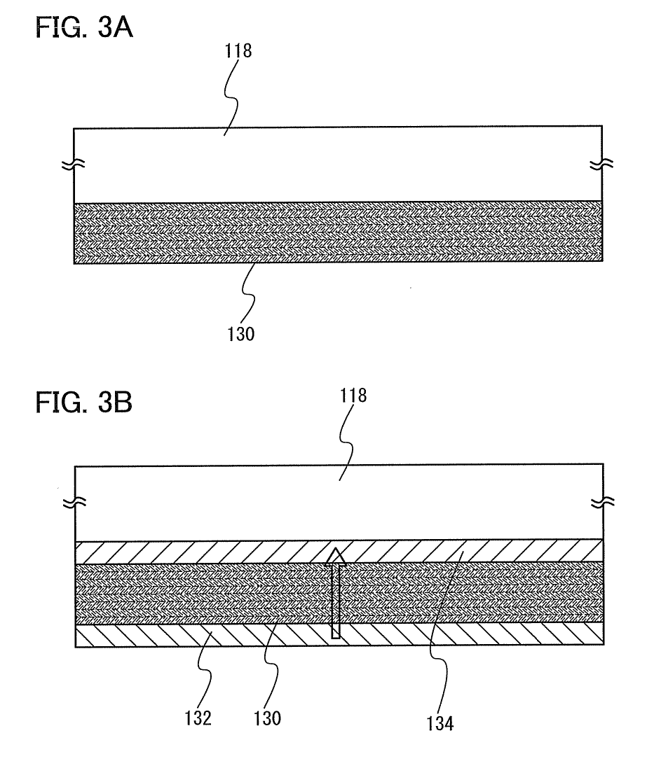

As shown in FIG. 3A, by disposing a plurality of evaporation sources at different positions, a thin film in which a plurality of materials are mixed, a thin film in which layers formed using a plurality of materials are arranged in a grid pattern, or a thin film in which a plurality of monomolecular layers (each having a thickness of 0.1 to 10 nm, typically 0.5 to 5 nm) of a plurality of materials are stacked in a film thickness direction (the state can also be substantially called a super multi-monomolecular-layers structure) can be formed as a thin film 130. As shown in FIG. 3B, by providing the thin film 130 so as to be interposed between a first electrode 132 and a second electrode 134, current can flow to pass through such a repeated structure. In this manner, the case where different materials are deposited at the same time while a substrate is spun at a high speed results in being different from the case using a conventional co-evaporation method.

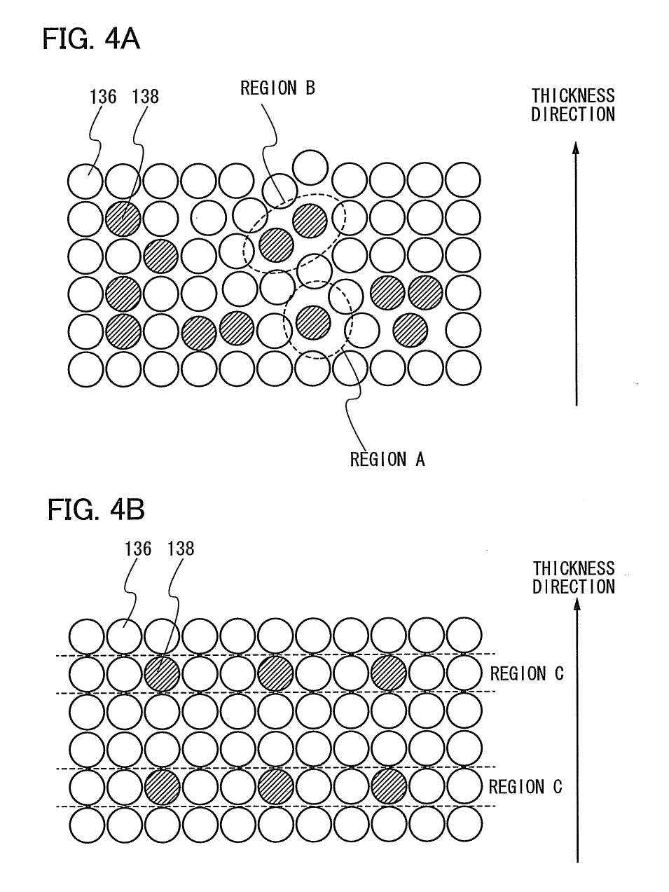

FIG. 4A is a conceptual diagram of the case where a guest material and a host material are co-evaporated. In the co-evaporation method, guest materials 138 and host materials 136 are not dispersed well; some guest materials are discrete as indicated by a region A and some guest materials agglutinate as indicated by a region B. Accordingly, local distortion of the host materials is caused. On the other hand, by spinning a substrate at a high speed and substantially depositing a monomolecular layer or a several-molecular layer when a surface of the substrate passes over an evaporation source, guest materials are arranged uniformly as shown in FIG. 4B, so that aggregation can be prevented. Accordingly, the guest materials are arranged uniformly as indicated by a region C, so that the guest materials and the host materials can be mixed uniformly

The spinning speed of the substrate serves as important parameters in relation to the amount of a film deposition material supplied from an evaporation source per unit time. In the case of a circular substrate which is spun at a fixed spinning rate, the linear speed is different between an inner circumference and an outer circumference of the circle, and therefore a thin film is formed such that the thickness is larger in the inner circumference than in the outer circumference when the amount of the film deposition material which is deposited on a substrate per unit time is the same in the outer circumference and the inner circumference of the circle. Therefore, in order to deposit a film deposition material so that the amount of the film deposition material on the inner circumference of the circular plate is less than that on the outer circumference, it is preferable that an evaporation source be disposed so as to be inclined or a shield for controlling the deposition amount of a film deposition material be provided. Then, by spinning at a speed at which a monomolecular layer is substantially formed by the film deposition material, such a thin film in which a plurality of materials is stacked uniformly or periodically as described above can be obtained. A spinning rate in the range from 300 rpm (rotation per minute) to 30000 rpm, typically 1000 rpm, is employed.

As the material of the substrate 118, various materials such as glass, ceramics, quartz, or plastic can be used. As a plastic material, polycarbonate, polyarylate, polyethersulfone, or the like can be selected.

The size of the substrate 118 is, for example, as large as that of an optical disc such as a CD-R. For example, a plastic substrate having a disc-like shape with a diameter of 100 mm to 140 mm, for example 120 mm, with a thickness of about 1.2 mm to 1.5 mm can be used. The diameter of the pass-through opening provided for the substrate 118 may be 5 mm to 20 mm (for example 15 mm). The shape of the substrate 118 is not limited to a circle but may be an ellipse or a rectangle.

### (Structural Embodiment of Evaporation Source)

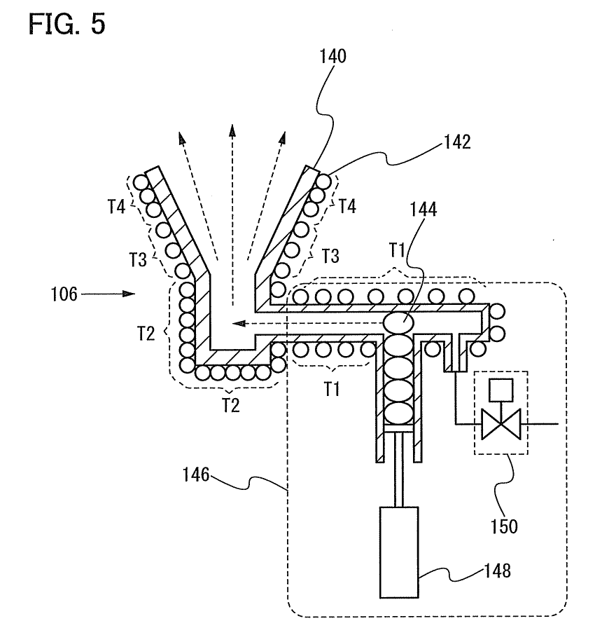

FIG. 5 illustrates one example of an evaporation source. A first evaporation source 106 in this embodiment includes a crucible 140 and a heater 142 which heats the crucible 140. One example of the heater 142 is as follows: an electrically-conducting path is formed by a conductor having high electrical resistance, such as a nichrome wire, and current is supplied therethrough, so that heat is generated. The same structure can be applied to a second evaporation source 108.

The first evaporation source 106 may be provided with a material supplying portion 146 for supplying a film deposition material 144 into the crucible 140, in order to perform intermittent evaporation of the material used for the film deposition. The material supplying portion 146 includes a container 148 of the film deposition material 144 and a pushing portion 150.

In that case, the amount of the film deposition material 144 which is enough for one film deposition treatment (per substrate) may be prepared, and it is preferable that the film deposition material 144 be solidified into a predetermined shape.

The method for supplying this film deposition material 144 into the crucible 140 is not particularly limited. For example, the container 148 may be connected to the crucible 140 via a narrow tube such that the film deposition material 144 is pushed mechanically or by pressure to pass through the narrow tube. In the case where the film deposition material 144 is pushed by pressure, an inert gas such as argon may be used and a valve which can be opened and closed within 0.5 minute, such as a piezoelectric valve, may be used to supply a compressed gas in a pulsed manner.

The material supplying portion 146 enables supplying of the film deposition material 144 to each substrate and enables the deposition of the film deposition material 144 to stop during a period for carrying the substrate in and out of the film deposition chamber, whereby the waste of the film deposition material 144 can be avoided.

In order to avoid the waste of the material which is evaporated or sublimed, it is preferable that the temperature of the crucible 140 be different depending on the position. A temperature (T2) of the bottom of the crucible 140 to which the film deposition material 144 is supplied is heated to a temperature which is equal to or higher than a temperature at which the film deposition material 144 is evaporated in order to heat the film deposition material 144 rapidly to generate vapor. The top end (discharge outlet) of the crucible 140 is heated to a temperature (T4) which may be lower than the temperature T2 but is as high as the temperature at which the evaporated vapor of the film deposition material 144 is prevented from being attached again to be deposited on the crucible 140. The crucible 140 in the portion between the bottom and the top end thereof is set to have a temperature (T3) between the temperatures T2 and T4. It is preferable that the narrow tube for connecting the crucible 140 and the container 148 be heated in advance to a temperature (T1) at which the film deposition material 144 is not evaporated.

By the first evaporation source 106 having the above-described structure, generation of vapor of the film deposition material 144 can be controlled, so that a thin film can be formed continuously on a plurality of substrates while the waste of film deposition material 144 can be avoided.

### (Structural Embodiment of Film Deposition Apparatus)

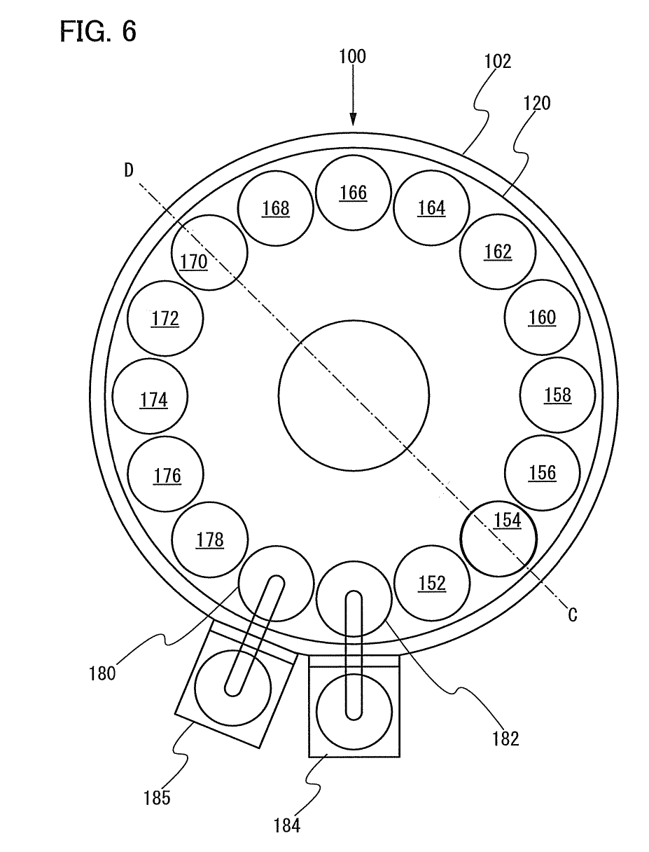

FIG. 6 is a plane view illustrating an example of a film deposition apparatus including a plurality of film deposition chambers. Each film deposition chamber has the same structure as the film deposition chamber described using FIGS. 1 and 2.

This film deposition apparatus 100 is disposed in a treatment chamber 102 capable of being vacuum evacuated and kept to be in the reduced-pressure state. A plurality of film deposition chambers can be disposed in the treatment chamber 102. A substrate is transferred to the film deposition chamber by a transfer table 120, whereby films having different compositions can be formed consecutively.

A substrate carrier chamber 184 is coupled to the treatment chamber 102 via a gate valve. The substrate carrier chamber 184 carries a substrate before film deposition into the treatment chamber 102, and carries the substrate after the film deposition out of the treatment chamber 102.

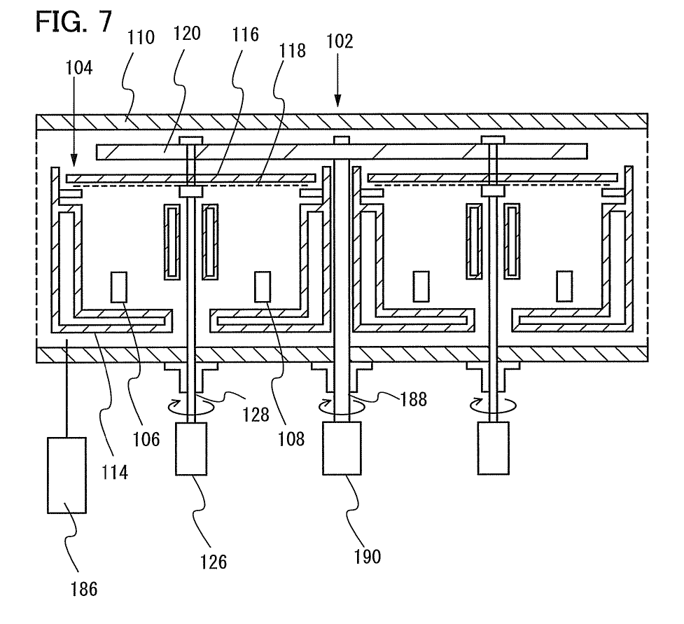

FIG. 7 is a schematic view of the cross-sectional structure along cut line C-D in FIG. 6. The structure of each film deposition chamber disposed in the treatment chamber 102 is the same as that shown in FIG. 1. The treatment chamber 102 is vacuum evacuated by a vacuum pump 186. A plurality of film deposition chambers is disposed in this treatment chamber 102.

A substrate 118 held by a substrate holder 116 is transferred from one film deposition chamber to another film deposition chamber by the transfer table 120. The substrate holder 116 is coupled to the transfer table 120. The transfer table 120 is coupled to a transfer driving portion 190 by a transfer rotation axis 188. The transfer driving portion 190 is turned to transfer the substrate 118 in the treatment chamber 102.

### (Operation of Film Deposition Apparatus and Manufacturing Method of Lighting Device)

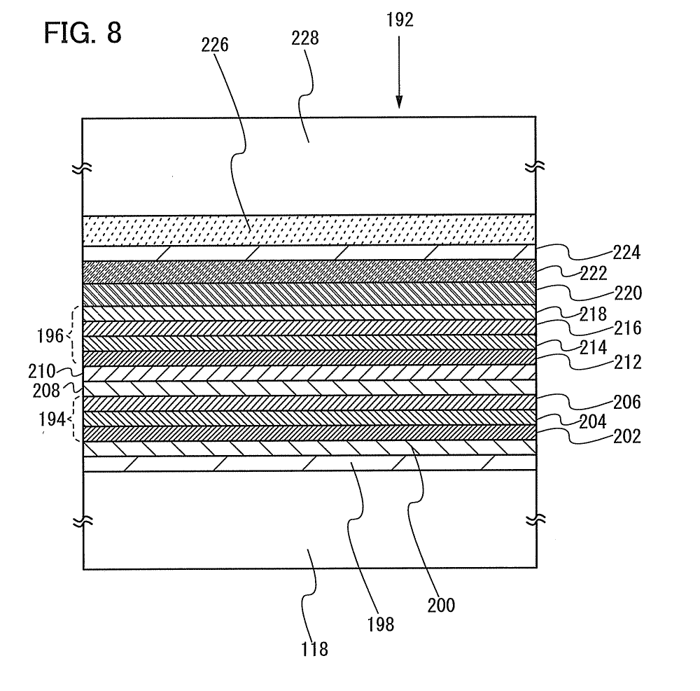

An operation of the film deposition apparatus shown in FIG. 6 will be described. The case where a lighting device 192 having a structure shown in FIG. 8 is manufactured using a film deposition apparatus is described as an example below. FIG. 8 is a view showing a main portion of the lighting device. This lighting device includes a plurality of stacked light-emission units each including an electroluminescent material interposed between a pair of electrodes.

A substrate 118 included in the lighting device 192 is carried from a substrate carrier chamber 184 into a treatment chamber 102 through a preliminary chamber 182. In a 1st film deposition chamber 152, a first insulating film 198 is formed. The first insulating film 198 is formed including an insulating film using silicon oxide, silicon nitride, silicon nitride oxide, zinc sulfide including silicon oxide, or the like. The first insulating film 198 can prevent moisture from entering an electroluminescent element; this is effective particularly in the case where a material having high moisture transmittivity, such as plastic is used as the substrate 118.

The substrate 118 provided with the first insulating film 198 is transferred from the 1st film deposition chamber 152 to a 2nd film deposition chamber 154 by operating the transfer table 120. Along with this operation, a new substrate is carried from the substrate carrier chamber 184 into the treatment chamber 102. In the 2nd film deposition chamber 154, a first electrode 200 is formed on the first insulating film 198. The first electrode 200 is used as an anode or a cathode of the electroluminescent element.

After the film deposition of the first electrode 200, the substrate 118 is transferred to a 3rd film deposition chamber 156. Along with this operation, a new substrate is carried from the substrate carrier chamber 184 into the treatment chamber 102, and the substrate in the 1st film deposition chamber 152 is transferred to the 2nd film deposition chamber 154. Such an operation is performed consecutively.

Over the substrate 118, a first light-emission unit 194 using the electroluminescent element is formed through a process in which the substrate 118 is transferred from the 3rd film deposition chamber 156 to a 5th film deposition chamber 160 though a 4th film deposition chamber 158. In the first light-emission unit 194, a hole injecting/transporting layer 202, a light-emitting layer 204, and an electron injecting/transporting layer 206 are stacked. Here, the hole injecting/transporting layer 202 is formed in the 3rd film deposition chamber 156, the light-emitting layer 204 is formed in the 4th film deposition chamber 158, and the electron injecting/transporting layer 206 is thinned in the 5th film deposition chamber 160. The structure of the first light-emission unit 194 is not limited to the above-described structure as long as the light-emitting layer 204 is included. The stacked-layer structure of the first light-emission unit 194 can be changed by changing the structure of the treatment chamber as appropriate.

The substrate 118 provided with the first light-emission unit 194 is transferred to a 6th film deposition chamber 162. In the 6th film deposition chamber 162, a first intermediate layer 208 is formed on the first light-emission unit 194. The first intermediate layer 208 is formed as a layer including an organic compound having a high hole-transporting property and a substance having an electron-accepting property (acceptor).

In a 7th film deposition chamber 164, a second intermediate layer 210 is formed on the first intermediate layer 208. The second intermediate layer 210 is formed as a layer including an organic compound having a high electron-transporting property and a substance having an electron-donating property (donor). The first intermediate layer 208 injects electrons into the first light-emission unit 194 and the second intermediate layer 210 injects holes into a second light-emission unit 196. The structure of the intermediate layer is not limited to the above but may be a single layer structure of a layer including an organic compound having a high hole-transporting property and a substance having an electron-accepting property (acceptor) or a layer including an organic compound having a high electron-transporting property and a substance having an electron-donating property (donor).

Over the substrate 118 provided with the second intermediate layer 210, the second light-emission unit 196 using an electroluminescent element is formed through a process in which the substrate 118 is transferred from a 8th film deposition chamber 166 to a 11th film deposition chamber 172 through 9th and 10th film deposition chambers 168 and 170. In the second light-emission unit 196, a hole injecting/transporting layer 212, a light-emitting layer 214, an electron transporting layer 216, and an electron-injecting layer 218 are stacked.

The hole injecting/transporting layer 212 is formed in the 8th film deposition chamber 166, the light-emitting layer 214 is formed in a 9th film deposition chamber 168, the electron transporting layer 216 is formed in a 10th film deposition chamber 170, and the electron-injecting layer 218 is formed in the 11th film deposition chamber 172.

When a light emission color of the first light-emission unit 194 and a light emission color of the second light-emission unit 196 are complementary to each other, white light emission can be extracted to the outside. Alternatively, each of the first light-emission unit 194 and the second light-emission unit 196 may include a plurality of light-emission layers, and light emission colors which are complementary to each other may be overlapped in the plurality of light-emission layers, so that white light emission can be obtained from each light-emission unit. As examples of a combination of complementary colors, color combinations of blue and yellow, blue-green and red, and the like can be given.

The substrate 118 provided with the second light-emission unit 196 is transferred to a 12th film deposition chamber 174. In the 12th film deposition chamber 174, a second electrode 220 is formed on the second light-emission unit 196.

Then, the substrate 118 provided with the second electrode 220 is transferred to a 13th film deposition chamber 176. In the 13th film deposition chamber 176, a drying layer 222 is formed on the second electrode 220. By the drying layer 222, degradation of the electroluminescent element due to moisture or the like can be prevented. As a drying agent, a substance which adsorbs moisture by chemical adsorption, such as an oxide of an alkaline earth metal such as calcium oxide or barium oxide can be used. As another example of the drying agent, a substance which adsorbs moisture by physical adsorption, such as zeolite or silica gel may be used.

The substrate 118 provided with the drying layer 222 is transferred to a 14th film deposition chamber 178. In the 14th film deposition chamber 178, a second insulating film 224 is formed on the drying layer 222. The second insulating film 224 prevents moisture, an impurity, or the like from the outside from entering the electroluminescent element.

The substrate 118 provided with the second insulating film 224 is transferred to a 15th film deposition chamber 180. In the 15th film deposition chamber 180, a sealing substrate 228 provided with a photo-curable or heat-curable sealant 226, which is carried from a sealing substrate carrier chamber 185, is overlapped with the second insulating film 224 of the substrate 118. Then, cure treatment of the sealant is performed thereon. As a material of the sealing substrate 228, a variety of materials such as glass, ceramic, quartz, or plastic can be selected. As a plastic material, polycarbonate, polyarylate, polyether sulfone, or the like can be selected. Note that the sealing substrate 228 is not necessarily provided; without providing the sealing substrate 228, the substrate 118 may be carried out of the film deposition apparatus after the electroluminescent element is sealed by a sealing film. Then, the substrate 118 is carried into the substrate carrier chamber 184 through the preliminary chamber.

By the above process the lighting device 192 can be manufactured by stacking the thin films consecutively without being exposed to the air throughout the process in the treatment chamber 102. According to this film deposition apparatus 100, guest materials can be dispersed without agglutinating among host materials, so that a lighting device with high luminous efficiency can be manufactured.

### (Example of Lighting Device)

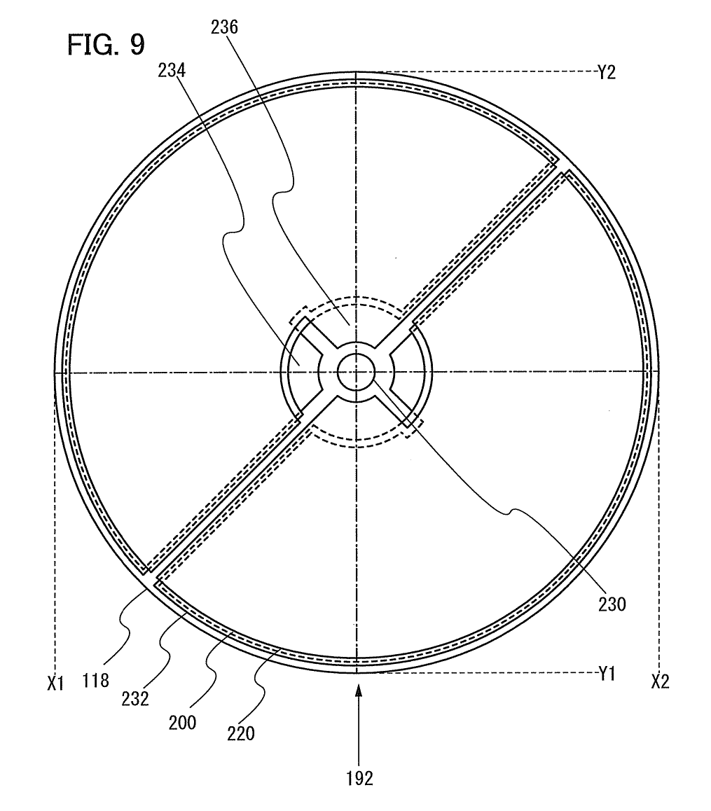

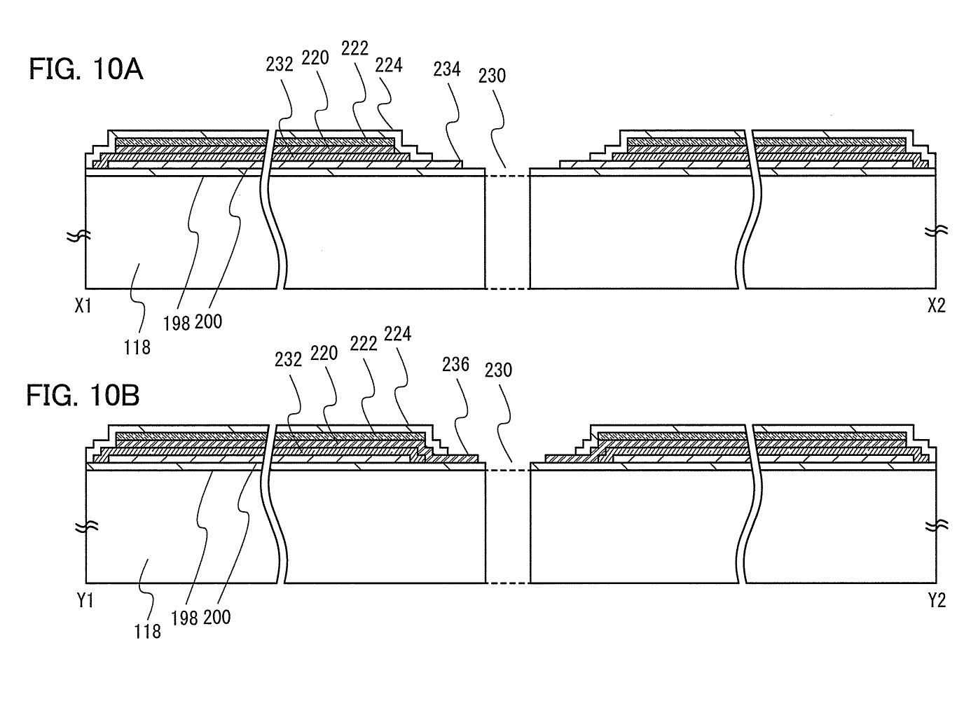

An example of a lighting device capable of being manufactured using the film deposition apparatus shown in FIG. 6 will be described using FIGS. 9 and 10. FIG. 9 is a plane view of the lighting device, cross-sectional structures along cut lines X1-X2 and Y1-Y2 in FIG. 9 are shown in FIGS. 10A and 10B, respectively.

In a lighting device 192, a first insulating film 198, a first electrode 200, a light-emission unit 232, a second electrode 220, a drying layer 222, and a second insulating film 224 are stacked on a substrate 118 having an opening portion 230 in a center portion thereof, and a first connection portion 234 and a second connection portion 236 are provided near the opening portion 230 of the substrate 118.

It is preferable that the light-emission unit 232 have a tandem structure in which a first light-emission unit 194 and a second light-emission unit 196 are stacked as shown in FIG. 8, in which case the current efficiency of the light-emission luminance can be increased and white light emission can be easily attained.

The second insulating film 224 has an opening portion in the center portion of the substrate 118, and the first connection portion 234 and the second connection portion 236 are exposed in the opening portion. The first connection portion 234 is electrically connected to the first electrode 200; the first connection portion 234 is formed by expending the first electrode 200 here. The second connection portion 236 is electrically connected to the second electrode 220; the second connection portion 236 is formed by expending the second electrode 220 here.

In the case where the first connection portion 234 and the second connection portion 236 are formed by extending the first electrode 200 and the second electrode 220 respectively as described above, the thickness of the lighting device 192 can be reduced.

The substrate 118 having the opening portion 230 is used and the first connection portion 234 and the second connection portion 236 are provided around the center portion of the substrate 118, so that the lighting device 192 can be powered around the center portion of the substrate 118. The opening portion 230 makes it easy for the substrate 118 to be fixed to a socket.

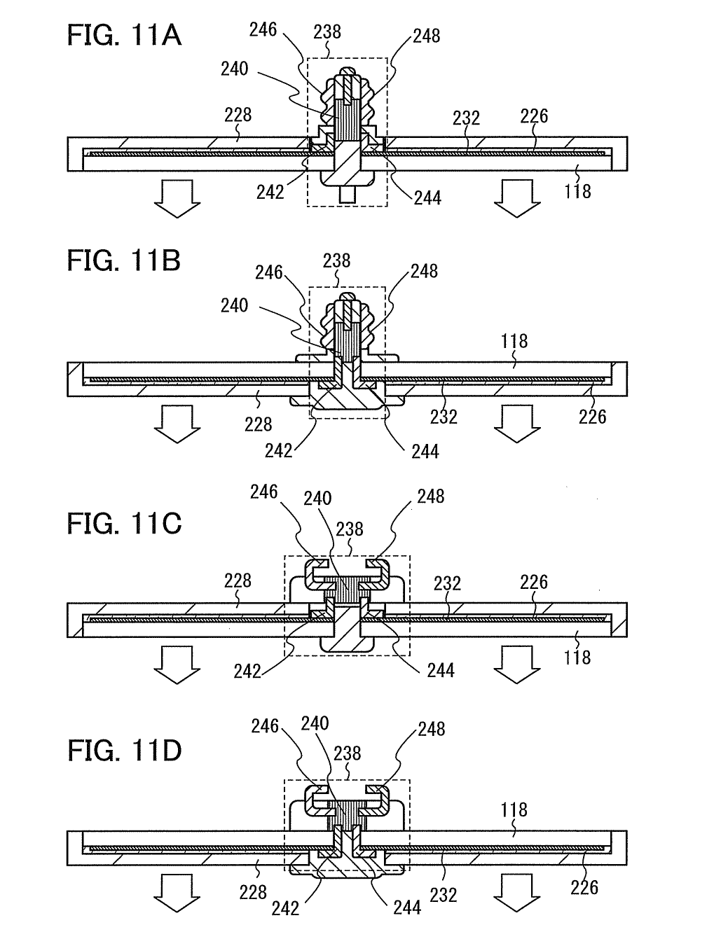

FIGS. 11A to 11D illustrate structures in which a connection member 238 is provided for the lighting device 192. The connection member 238 may be called a cap or a socket. The connection member 238 includes a control circuit 240, a first connection wiring 242, a second connection wiring 244, a first leading wiring 246, and a second leading wiring 248. The control circuit 240 serves to make the lighting device 192 emit light on the basis of a power source voltage supplied from a power source.

The first connection wiring 242 of the connection member 238 is connected to the first connection portion 234, and the second connection wiring 244 of the connection member 238 is connected to the second connection portion 236. Electrical connection between the first connection wiring 242 and the first connection portion 234 and electrical connection between the second connection wiring 244 and the second connection portion 236 can be performed by anisotropic conductive paste (ACP), an anisotropic conducive film (ACF), conductive paste, or solder bonding. The first leading wiring 246 and the second leading wiring 248 are electrically connected to the control circuit 240 and each function as a wiring for supplying power to the lighting device 192.

FIG. 11A illustrates a structure (bottom-emission structure) in which light is taken out from the plane on the substrate 118 side though the substrate 118; in that case, the control circuit 240 of the connection member 238 can be provided above the sealing substrate 228.

FIG. 11B may illustrate a structure (top-emission structure) in which light is taken out from the plane on the sealing substrate 228 side (which is opposite to the substrate 118 side). In that case, the control circuit 240 is provided on the rear surface side of the substrate 118, and the first connection wiring 242 and the second connection wiring 244 are electrically connected to the lighting device 192 through the opening portion provided in the substrate 118.

FIGS. 11A and 11B illustrate the structures in which a fitting portion of the connection member 238 also serves as the first leading wiring 246 and a contact portion of the connection member 238 is connected to the second leading wiring 248. Alternatively, as shown in FIGS. 11C and 11D, two fitting portions of the connection member 238 also serve as the first leading wiring 246 and the second leading wiring 248.

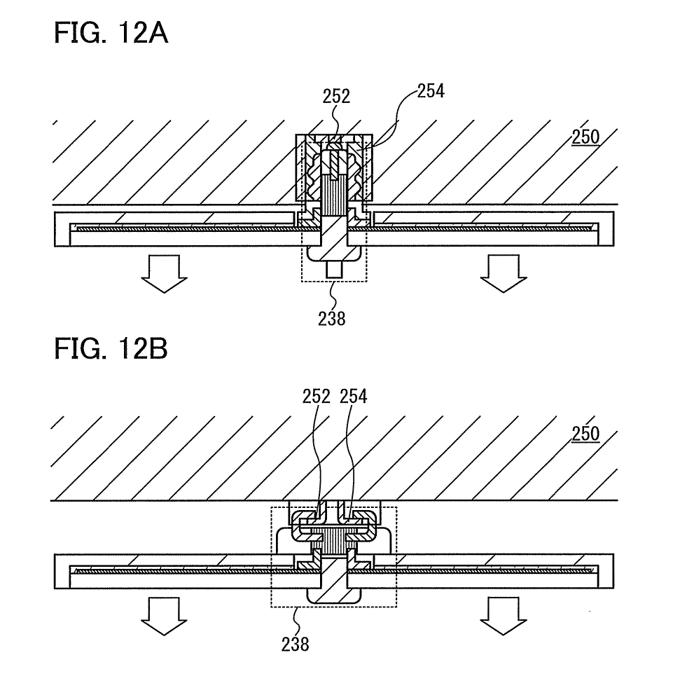

Next, FIGS. 12A and 12B illustrate examples of a usage pattern of the lightning device 191 provided with the connection member 238. Shown in FIGS. 12A and 12B are the cases where the connection member 238 provided for the lightning device 191 is provided on a ceiling 250.

A first external electrode 252 and a second external electrode 254 are provided on the ceiling 250. The first external electrode 252 is electrically connected to the first leading wiring 246 provided for the connection member 238, and the second external electrode 254 is electrically connected to the second leading wiring 248, so that power is supplied to the control circuit 240 from the outside.

In the structure shown in FIG. 12A, the diameter of the connection member 238 can be determined depending on the size of an attachment portion of the ceiling 250; it can be 10 mm to 40 mm (for example, 26 mm). FIG. 12A illustrates the case where the structure shown in FIG. 11A is attached on the ceiling 250 and FIG. 12B illustrates the case where the structure shown in FIG. 11C is attached to the ceiling 250; however, another structure can be attached as well. Such a structure is not necessarily attached on the ceiling 250 but may be buried in a wall or a floor.

This application is based on Japanese Patent Application serial no. 2009-080199 filed with Japan Patent Office on Mar. 27, 2009, the entire contents of which are hereby incorporated by reference.

What is claimed is:

1. A film deposition apparatus comprising:
a plurality of evaporation sources disposed discretely;
a substrate holding portion configured to hold a substrate such that in-plane positions of the substrate, at which film deposition materials are deposited from the plurality of evaporation sources, are different; and
a driving portion configured to move either one or both of the plurality of evaporation sources and the substrate relatively.

2. The film deposition apparatus according to claim 1, wherein the driving portion is configured to spin the substrate using a center of the substrate as a center of spinning.

3. The film deposition apparatus according to claim 2, wherein a spinning rate for spinning the substrate by the driving portion is equal to or greater than 300 rotations per minute and equal to or less than 30000 rotations per minute.

4. The film deposition apparatus according to claim 1, wherein the substrate is a circular substrate.

5. A film deposition apparatus comprising:
a first evaporation source having a first film deposition material so as to deposit the first film deposition material on a first region in a surface of a substrate;
a second evaporation source having a second film deposition material so as to deposit the second film deposition material on a second region in the surface of the substrate;
a substrate holding portion configured to face the surface of the substrate and the first and second evaporation sources; and
a driving portion configured to move the substrate and either one or both of the first and second evaporation sources relatively while depositing the first and second film deposition materials on the surface of the substrate.

6. The film deposition apparatus according to claim 5, wherein the driving portion is configured to spin the substrate using a center of the substrate as a center of spinning.

7. The film deposition apparatus according to claim 6, wherein a spinning rate for spinning the substrate by the driving portion is equal to or greater than 300 rotations per minute and equal to or less than 30000 rotations per minute.

8. The film deposition apparatus according to claim 5, wherein the substrate is a circular substrate.

9. The film deposition apparatus according to claim 5, the first region and the second region are not overlapped each other on the surface of the substrate.

10. A film deposition method comprising the steps of:
setting a substrate on a substrate holding portion in a chamber;
disposing a first evaporation source having a first film deposition material in the chamber so as to deposit the first film deposition material on a first region in a surface of the substrate at a certain moment;
disposing a second evaporation source having a second film deposition material in the chamber so as to deposit the second film deposition material on a second region in the surface of the substrate at the certain moment; and
relatively moving either one or both of the substrate and the first and second evaporation sources during deposition of the first and second film deposition materials on the surface of the substrate.

11. The film deposition method according to claim 10, wherein a host material is supplied from the first evaporation source and a guest material is supplied from the second evaporation source.

12. The film deposition method according to claim 10, the first region and the second region are not overlapped each other on the surface of the substrate.

13. A method for manufacturing an electroluminescent element using the film deposition method according to claim 10.

14. A method for manufacturing a lighting device using the film deposition method according to claim 10.

15. A film deposition method comprising the steps of:
setting a substrate on a substrate holding portion in a chamber;
disposing a first evaporation source having a first film deposition material in the chamber so as to deposit the first film deposition material on a first region in a surface of the substrate;
disposing a second evaporation source having a second film deposition material in the chamber so as to deposit the second film deposition material a second region in the surface of the substrate; and
depositing the first film deposition material supplied from the first evaporation source and the second film deposition material supplied from the second evaporation source on the surface of the substrate while spinning the substrate.

16. The film deposition method according to claim 15, wherein a spinning rate of the substrate is equal to or greater than 300 rotations per minute and equal to or less than 30000 rotations per minute.

17. The film deposition method according to claim 15, wherein a host material is supplied from the first evaporation source and a guest material is supplied from the second evaporation source.

18. The film deposition method according to claim 15, the first region and the second region are not overlapped each other on the surface of the substrate.

19. A method for manufacturing an electroluminescent element using the film deposition method according to claim 15.

20. A method for manufacturing a lighting device using the film deposition method according to claim 15.
